(19) United States
(12) Patent Application Publication
(10) Pub. No.: US 2015/0263157 A1
(43) Pub. Date: Sep. 17, 2015

(54) SEMICONDUCTOR DEVICE

(71) Applicant: Kabushiki Kaisha Toshiba, Tokyo (JP)

(72) Inventor: Hidetoshi Fujimoto, Kawasaki Kanagawa (JP)

(21) Appl. No.: 14/488,602

(22) Filed: Sep. 17, 2014

(30) Foreign Application Priority Data
Mar. 14, 2014 (JP) 2014-052735

(51) Int. Cl. H01L 29/78; H01L 29/20; H01L 29/36; H01L 29/10

(52) U.S. Cl. CPC H01L 29/7802; H01L 29/1095; H01L 29/2003; H01L 29/36

(57) ABSTRACT

A semiconductor device of an embodiment includes: an n-type nitride semiconductor layer; an insulating layer selectively provided on the nitride semiconductor layer; an n-type first nitride semiconductor region provided on the nitride semiconductor layer and the insulating layer; an n-type second nitride semiconductor region provided on the insulating layer; a p-type third nitride semiconductor region provided between the first nitride semiconductor region and the second nitride semiconductor region; a gate insulating film provided on the third nitride semiconductor region; a gate electrode provided on the gate insulating film; a first electrode electrically connected to the second nitride semiconductor region; and a second electrode that is provided on the opposite side of the nitride semiconductor layer from the insulating layer, and is electrically connected to the nitride semiconductor layer.

### CROSS-REFERENCE TO RELATED APPLICATION

This application is based upon and claims the benefit of priority from Japanese Patent Application No. 2014-052735, filed on Mar. 14, 2014, the entire contents of which are incorporated herein by reference.

### FIELD

Embodiments described herein relate generally to a semiconductor device.

### BACKGROUND

Nitride semiconductors having high dielectric breakdown strengths are expected to be applied to semiconductor devices for power electronics, high-frequency power semiconductor devices, or the like. So as to achieve higher breakdown voltages and higher degrees of integration, vertical devices have been expected.

As for a p-type nitride semiconductor, it is difficult to increase an impurity activation ratio with impurity doping using an ion implantation. Therefore, it is difficult to adjust the threshold value of a switching device having a p-type nitride semiconductor as a channel layer, and switching characteristics thereof do not become stable. Further, in a switching device manufactured by using an ion implantation, pn junction capacitance turns into parasitic capacitance, and switching characteristics are degraded.

### BRIEF DESCRIPTION OF THE DRAWINGS

FIG. 1 is a schematic cross-sectional view of a semiconductor device of a first embodiment;

FIG. 2 is a schematic cross-sectional view of the semiconductor device being manufactured by a semiconductor device manufacturing method of the first embodiment;

FIG. 3 is a schematic cross-sectional view of the semiconductor device being manufactured by the semiconductor device manufacturing method of the first embodiment;

FIG. 4 is a schematic cross-sectional view of the semiconductor device being manufactured by the semiconductor device manufacturing method of the first embodiment;

FIG. 5 is a schematic cross-sectional view of the semiconductor device being manufactured by the semiconductor device manufacturing method of the first embodiment;

FIG. 6 is a schematic cross-sectional view of the semiconductor device being manufactured by the semiconductor device manufacturing method of the first embodiment;

FIG. 7 is a schematic cross-sectional view of the semiconductor device being manufactured by the semiconductor device manufacturing method of the first embodiment;

FIG. 8 is a schematic cross-sectional view of a semiconductor device as a modification of the first embodiment;

FIG. 9 is a schematic cross-sectional view of a semiconductor device of a second embodiment;

FIG. 10 is a schematic cross-sectional view of the semiconductor device being manufactured by a semiconductor device manufacturing method of the second embodiment;

FIG. 11 is a schematic cross-sectional view of the semiconductor device being manufactured by the semiconductor device manufacturing method of the second embodiment;

FIG. 12 is a schematic cross-sectional view of the semiconductor device being manufactured by the semiconductor device manufacturing method of the second embodiment; and

FIG. 13 is a schematic cross-sectional view of a semiconductor device of a third embodiment.

### DETAILED DESCRIPTION

A semiconductor device of an embodiment includes: an n-type nitride semiconductor layer; an insulating layer selectively provided above the nitride semiconductor layer; an n-type first nitride semiconductor region provided above the nitride semiconductor layer and the insulating layer; an n-type second nitride semiconductor region provided above the insulating layer; a p-type third nitride semiconductor region provided between the first nitride semiconductor region and the second nitride semiconductor region; a gate insulating film provided above the third nitride semiconductor region; a gate electrode provided above the gate insulating film; a first electrode electrically connected to the second nitride semiconductor region; and a second electrode that is provided above the opposite side of the nitride semiconductor layer from the insulating layer, and is electrically connected to the nitride semiconductor layer.

The following is a description of embodiments, with reference to the accompanying drawings. In the following description, like components are denoted by like reference numerals, and explanation of components described once will not be repeated.

In this specification, a “nitride semiconductor” is a GaN-based semiconductor, for example. “GaN-based semiconductor” is a general term for semiconductors such as GaN (gallium nitride), AlN (aluminum nitride), and InN (indium nitride), and semiconductors having intermediate compositions of those semiconductors.

In the following description, n⁺, n, n⁻, p⁺, p, and p⁻ indicate relative levels of impurity concentrations in the respective conductivity types. Specifically, the concentration of an n⁺-type impurity is relatively higher than the concentration of the corresponding n-type impurity, and the concentration of an n⁻-type impurity is relatively lower than the concentration of the corresponding n-type impurity. Likewise, the concentration of a p⁺-type impurity is relatively higher than the concentration of the corresponding p-type impurity, and the concentration of a p⁻-type impurity is relatively lower than the concentration of the corresponding p-type impurity. It should be noted that there are cases where an n⁺-type and an n⁻-type are referred to simply as an n-type, and a p⁺-type and a p⁻-type are referred to simply as a p-type.

### First Embodiment

A semiconductor device of this embodiment includes: an n-type nitride semiconductor layer; an insulating layer selectively formed on or above the nitride semiconductor layer;

an n-type first nitride semiconductor region formed on or above the nitride semiconductor layer and the insulating layer; an n-type second nitride semiconductor region formed on or above the insulating layer; a p-type third nitride semiconductor region formed between the first nitride semiconductor region and the second nitride semiconductor region; a gate insulating film formed on or above the third nitride semiconductor region; a gate electrode formed on or above the gate insulating film; a first electrode electrically connected to the second nitride semiconductor region; and a second electrode that is formed on or above the opposite side of the nitride semiconductor layer from the insulating layer, and is electrically connected to the nitride semiconductor layer.

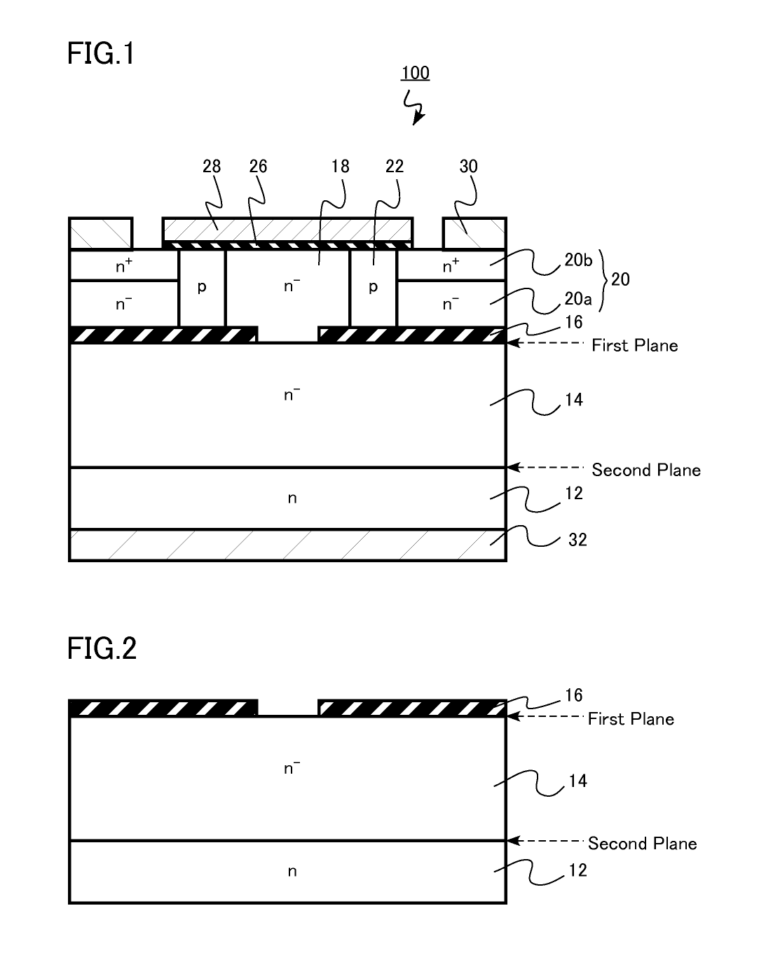

FIG. 1 is a schematic cross-sectional view of the semiconductor device of this embodiment. The semiconductor device of this embodiment is a MISFET (Metal Insulator Semiconductor Field Effect Transistor) 100 that is an n-channel transistor having electrons as carriers. The MISFET 100 is also a vertical transistor that causes carriers to travel between the source electrode on the surface side of the semiconductor substrate and the drain electrode on the bottom surface side.

This MISFET 100 includes an n-type GaN substrate (a nitride semiconductor substrate) 12, an n⁻-type GaN layer (the nitride semiconductor layer) 14, the insulating layer 16, an n⁻-type first GaN region (the first nitride semiconductor region) 18, an n-type second GaN region (the second nitride semiconductor region) 20, a p-type third GaN region (the third nitride semiconductor region) 22, the gate insulating film 26, the gate electrode 28, the source electrode (the first electrode) 30, and the drain electrode (the second electrode) 32.

The GaN substrate 12 functions as the drain region of the MISFET 100. The GaN substrate 12 contains Si (silicon) as the n-type impurity, for example. The GaN substrate 12 is a {0001} substrate, for example.

The n-type impurity concentration in the GaN substrate 12 is not lower than 1×10¹⁸ cm⁻³ and not higher than 1×10²⁰ cm⁻³, for example. The thickness of the GaN substrate 12 is not smaller than 50 nm and not greater than 300 nm, for example.

The n⁻-type GaN layer 14 is formed on the GaN substrate 12.

The GaN layer 14 functions as a drift layer of the MISFET 100. The GaN layer 14 contains Si (silicon) as the n-type impurity, for example. The n-type impurity concentration in the GaN layer 14 is not lower than 5×10¹⁵ cm⁻³ and not higher than 5×10¹⁷ cm⁻³, for example. The n-type impurity concentration in the GaN layer 14 is lower than the n-type impurity concentration in the GaN substrate 12. The thickness of the GaN layer 14 is not smaller than 5 μm and not greater than 20 μm, for example.

The insulating layer 16 is formed on the GaN layer 14. The insulating layer 16 is selectively formed on the GaN layer 14. The insulating layer 16 is a silicon oxide film, for example. The thickness of the insulating layer 16 is not smaller than 50 nm and not greater than 500 nm, for example.

The n⁻-type first GaN region 18 is formed on the GaN layer 14 and the insulating layer 16. The first GaN region 18 is in contact with the GaN layer 14 at an opening portion of the insulating layer 16.

The first GaN region 18 functions as a drift layer of the MISFET 100. The n-type impurity concentration in the first GaN region 18 is not lower than 5×10¹⁵ cm⁻³ and not higher than 5×10¹⁷ cm⁻³, for example.

So as to lower the on-state resistance of the MISFET 100, the n-type impurity concentration in the first GaN region 18 is preferably higher than the n-type impurity concentration in the GaN layer 14.

Further, so as to lower the on-state resistance of the MISFET 100, the thickness of the first GaN region 18 is preferably smaller than the thickness of the GaN layer 14. The thickness of the first GaN region 18 is not smaller than 50 nm and not greater than 500 nm, for example.

The n⁻-type second GaN region 20 is formed on the insulating layer 16. With the insulating layer 16 being interposed between the second GaN region 20 and the GaN layer 14, the second GaN region 20 is not in physical contact with the GaN layer 14.

The second GaN region 20 functions as the source region of the MISFET 100. The second GaN region 20 includes a low impurity concentration region 20a on the insulating layer 16, and a high impurity concentration region 20b on the low impurity concentration region 20a. The second GaN region 20 has a stack structure of the low impurity concentration region 20a and the high impurity concentration region 20b. The second GaN region 20 contains Si (silicon) as the n-type impurity, for example.

The n-type impurity concentration in the low impurity concentration region 20a is the same as the n-type impurity concentration in the first GaN region 18, for example. The n-type impurity concentration in the low impurity concentration region 20a is not lower than 5×10¹⁵ cm⁻³ and not higher than 5×10¹⁷ cm⁻³, for example.

The high impurity concentration region 20b serves to lower the contact resistance of the source electrode 30. The n-type impurity concentration in the high impurity concentration region 20b is higher than the n-type impurity concentration in the first GaN region 18. The n-type impurity concentration in the high impurity concentration region 20b is not lower than 1×10¹⁸ cm⁻³ and not higher than 1×10²² cm⁻³, for example.

The p-type third GaN region 22 in contact with the insulating layer 16 is formed on the portion of the insulating layer 16 between the first GaN region 18 and the second GaN region 20. The third GaN region 22 functions as the channel region of the MISFET 100. The third GaN region 22 is a single-crystal epitaxially grown layer.

The threshold value of the MISFET 100 is controlled by the p-type impurity concentration in the third GaN region 22. The p-type impurity concentration in the third GaN region 22 is not lower than 1×10¹⁷ cm⁻³ and not higher than 1×10¹⁹ cm⁻³, for example. The p-type carrier concentration in the third GaN region 22 is not lower than 1×10¹⁶ cm ⁻³ and not higher than 1×10¹⁸ cm⁻³, for example.

The gate insulating film 26 is formed on the third GaN region 22 and the first GaN region 18. The gate insulating film 26 is a silicon oxide film, for example. The thickness of the gate insulating film 26 is not smaller than 50 nm and not greater than 200 nm, for example.

The gate electrode 28 is formed on the gate insulating film 26. The gate electrode 28 is p-type polysilicon doped with B (boron) , or n-type polysilicon doped with P (phosphorus) , for example. Other than polysilicon, a metal silicide, a metal, or the like can be used as the gate electrode 28.

An interlayer insulating film (not shown), for example, is formed on the gate electrode 28. The interlayer insulating film is a silicon oxide film, for example.

The source electrode 30 that is electrically connected to the second GaN region 20 is then formed. The source electrode 30 is formed on the high impurity concentration region 20b.

The source electrode 30 and the high impurity concentration region 20b preferably form ohmic contact therebetween. The source electrode 30 has a stack structure of Ti (titanium)/Al (aluminum)/Ti (titanium), for example.

The drain electrode 32 electrically connected to the n-type GaN layer 14 is formed on the opposite side of the n-type GaN substrate 12 from the GaN layer 14. The drain electrode 32 has a stack structure of Ti (titanium)/Al (aluminum)/Ti (titanium), for example.

A well electrode (a third electrode, not shown) electrically connected to the third GaN region 22 is also formed. The same potential as the potential applied to the source electrode 30 is applied to the well electrode, for example.

Next, a method of manufacturing the semiconductor device of this embodiment is described.

FIGS. 2 through 7 are schematic cross-sectional views of the semiconductor device being manufactured by the semiconductor device manufacturing method of this embodiment.

First, the n-type GaN substrate 12 containing Si (silicon) as the n-type impurity at a concentration not lower than 1×10¹⁸ cm⁻³ and not higher than 1×10²⁰ cm⁻³, is prepared.

The n-type GaN layer 14 that contains Si as the n-type impurity at a concentration not lower than 5×10¹⁵ cm⁻³ and not higher than 5×10¹⁶ cm⁻³, for example, and has a thickness not smaller than 5 μm and not greater than 20 μm, for example, is then formed on the n-type GaN substrate 12 by an epitaxial growth technique. The epitaxial growth is performed by MOCVD (Metal Organic Chemical Vapor Deposition), for example.

The insulating layer 16 that is a silicon oxide film is then formed on the GaN layer 14 by CVD (Chemical Vapor Deposition), for example. After that, patterning is performed on the insulating layer 16 by photolithography and etching, to form an opening through which the GaN layer 14 is exposed (FIG. 2).

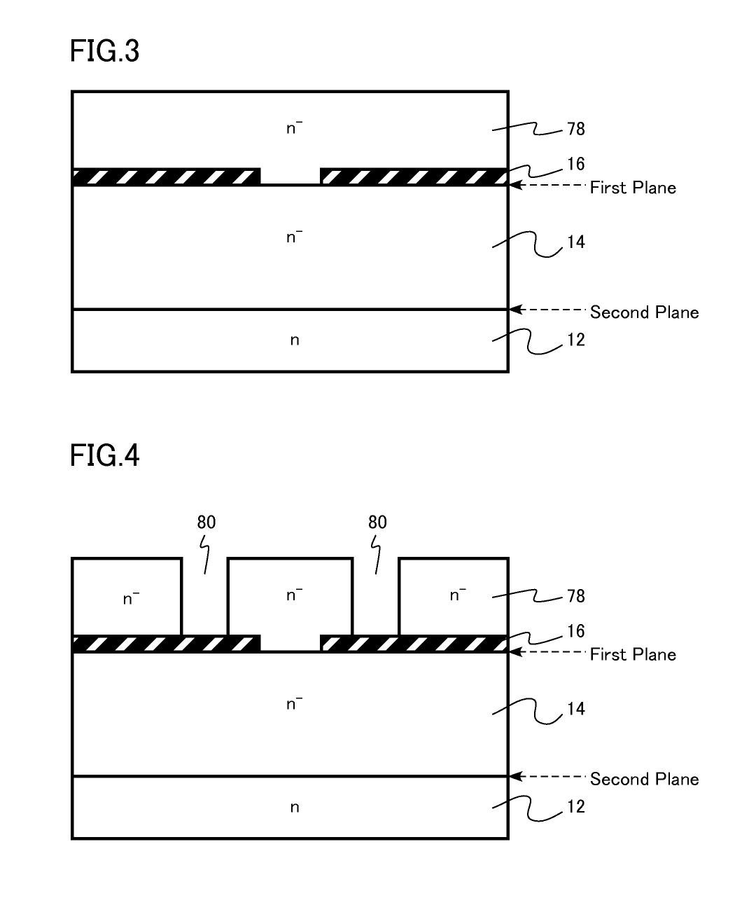

An n-type GaN layer 78 that contains Si as the n-type impurity at a concentration not lower than 5×10¹⁵ cm⁻³ and not higher than 5×10¹⁷ cm⁻³, for example, and has a thickness not smaller than 50 nm and not greater than 500 nm, for example, is formed on the GaN layer 14 and the insulating layer 16. The n-type GaN layer 78 is formed on the insulating layer 16, while the GaN layer 14 exposed through the opening serves as a seed crystal. The n-type GaN layer 78 is formed by so-called ELOG (Epitaxial Lateral OverGrowth) (FIG. 3).

Patterning is then performed by photolithography and etching, to form trenches 80 in the GaN layer 78 (FIG. 4). The trenches 80 are formed so that the insulating layer 16 is exposed through the bottom portions thereof.

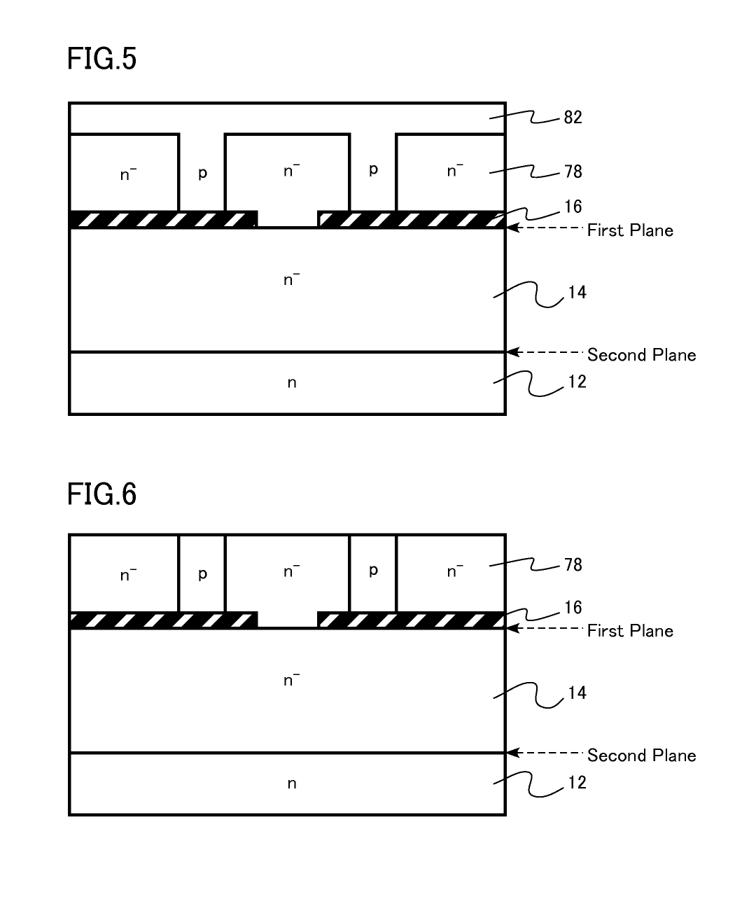

A p-type GaN layer 82 is then formed by an epitaxial growth technique (MOCVD), so as to fill the trenches 80 (FIG. 5). The p-type GaN layer 82 grows into a single-crystal layer, while the portions of the GaN layer 78 as the side surfaces of the trenches 80 and the surface of the GaN layer 78 serve as seed crystals.

The p-type impurity is Mg (magnesium), for example. The source gas may be trimethylgallium (TMG) or ammonia (NH₃), for example, and the p-type dopant in the source gas may be cyclopentadienylmagnesium (Cp₂Mg), for example.

The p-type GaN layer 82 is then polished by CMP (Chemical Mechanical Polishing) (FIG. 6).

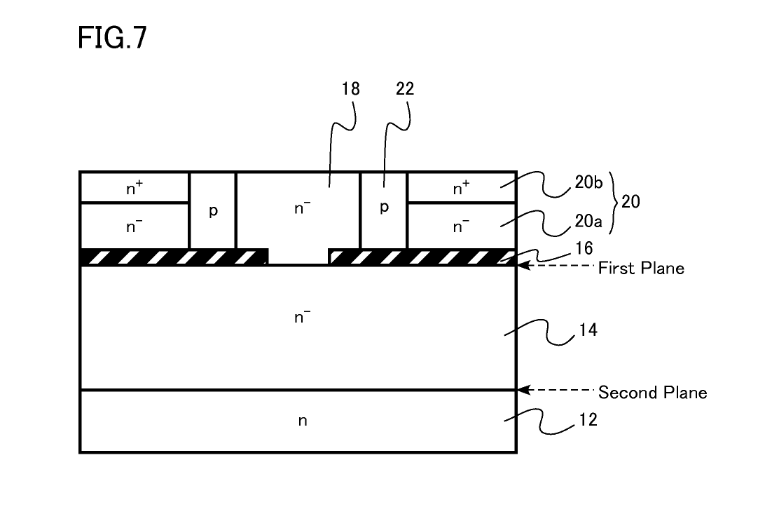

The high impurity concentration region 20b is then formed on part of the surface of the n-type GaN layer 78 by photolithography and an ion implantation technique (FIG. 7). The high impurity concentration region 20b is formed by implanting ions of Si as the n-type impurity, for example.

Through the above procedures, the first GaN region 18, the second GaN region 20, and the third GaN region 22 are formed.

After that, the gate insulating film 26, the gate electrode 28, the source electrode (the first electrode) 30, and the drain electrode (the second electrode) 32 are formed by a known manufacturing method. By the above described manufacturing method, the MISFET 100 shown in FIG. 1 is formed.

The action and effects of this embodiment are as follows.

When a p-type nitride semiconductor is formed, it is difficult to constantly achieve a sufficiently high p-type impurity activation rate if the p-type impurity doping is performed by an ion implantation technique. If the p-type impurity doping is performed by an epitaxial growth technique, on the other hand, a relatively high p-type impurity activation rate can be constantly achieved.

In the MISFET 100 of this embodiment, the bottom portion of the second GaN region (the second nitride semiconductor region) 20 to be the source region is in contact with the insulating layer 16. Accordingly, the parasitic capacitance of the source region becomes lower than in a case where a pn junction exists in the bottom portion of the source region. Thus, switching characteristics of the MISFET 100 are improved, and power consumption is reduced.

Further, in the MISFET 100 of this embodiment, the third GaN region (the third nitride semiconductor region) 22 that is made of a p-type semiconductor and is to be the channel region can be formed by an epitaxial growth technique. Accordingly, a high carrier concentration can be constantly achieved in the channel region. Thus, the threshold value of the MISFET 100 can be readily adjusted, and switching characteristics become stable.

Further, the bottom portion of the third GaN region (the third nitride semiconductor region) 22 to be the channel region is in contact with the insulating layer 16. Therefore, there exist no parasitic diodes (body diodes). Accordingly, characteristics degradation due to a parasitic diode can be avoided.

### Modification

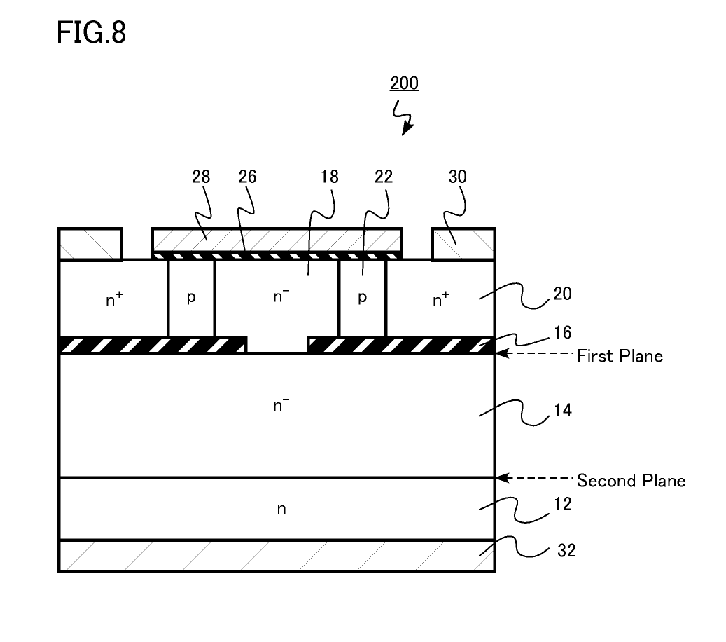

FIG. 8 is a schematic cross-sectional view of a semiconductor device as a modification of this embodiment. As shown in FIG. 8, in a MISFET 200 of this modification, the second GaN region 20 does not have a stack structure of a low impurity concentration region and a high impurity concentration region, and includes only a high impurity concentration region. With this modification, the same effects as those of the above described embodiment can be achieved.

### Second Embodiment

A semiconductor device of this embodiment is the same as the first embodiment, except that the third nitride semiconductor region is formed on the nitride semiconductor layer. Therefore, explanation of the same aspects as those of the first embodiment will not be repeated.

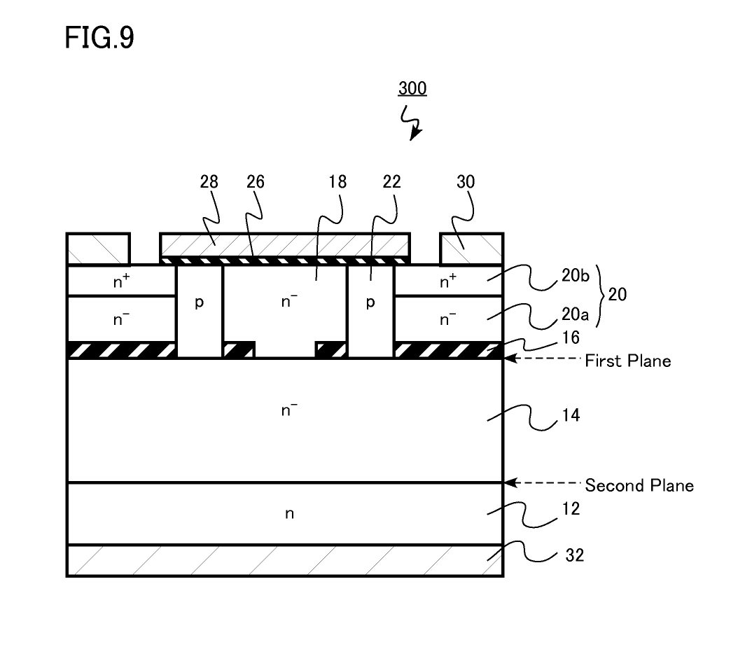

FIG. 9 is a schematic cross-sectional view of the semiconductor device of this embodiment.

As shown in FIG. 9, in a MISFET 300 of this embodiment, the p-type third GaN region (the third nitride semiconductor region) 22 is provided on and in contact with the n⁻-type GaN layer (the nitride semiconductor layer) 14.

Next, a method of manufacturing the semiconductor device of this embodiment is described.

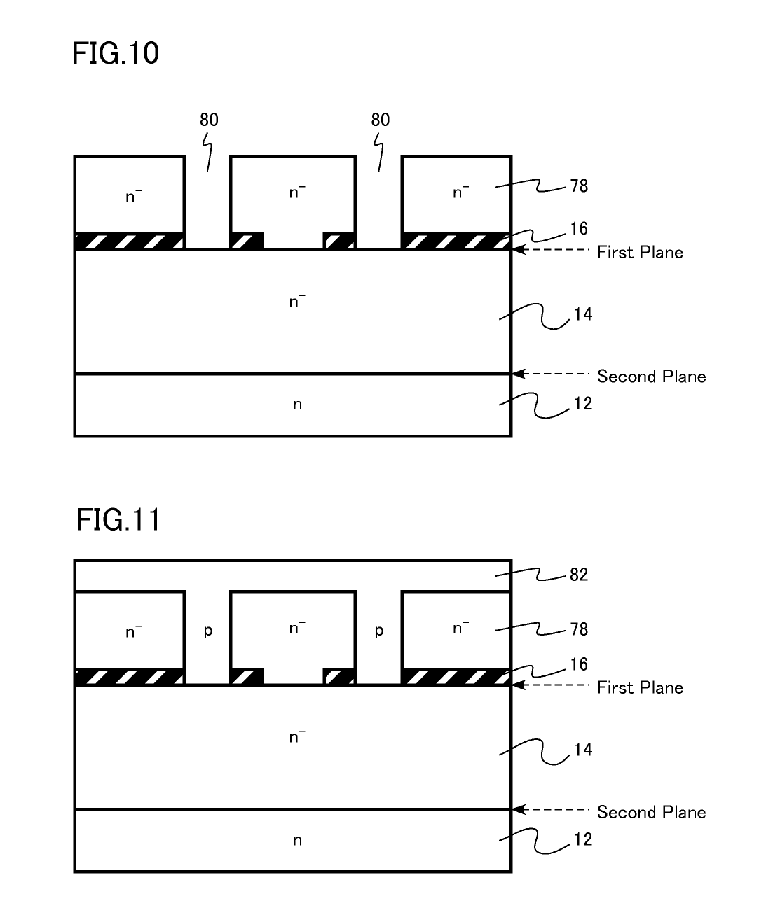

FIGS. 10 through 12 are schematic cross-sectional views of the semiconductor device being manufactured by the semiconductor device manufacturing method of this embodiment.

First, the procedures up to the formation of the n-type GaN layer 78 are the same as those of the first embodiment.

Patterning is then performed by photolithography and etching, to form trenches 80 in the GaN layer 78 (FIG. 10). In forming the trenches 80, etching is also performed on the insulating layer 16, to expose the n-type GaN layer 14 through the bottom portion thereof.

A p-type GaN layer 82 is then formed by an epitaxial growth technique, so as to fill the trenches 80 (FIG. 11) . The p-type GaN layer 82 grows into a single-crystal layer, while the portions of the GaN layer 14 as the bottom portions of the trenches 80, the portions of the GaN layer 78 as the side surfaces of the trenches 80, and the surface of the GaN layer 78 serve as seed crystals.

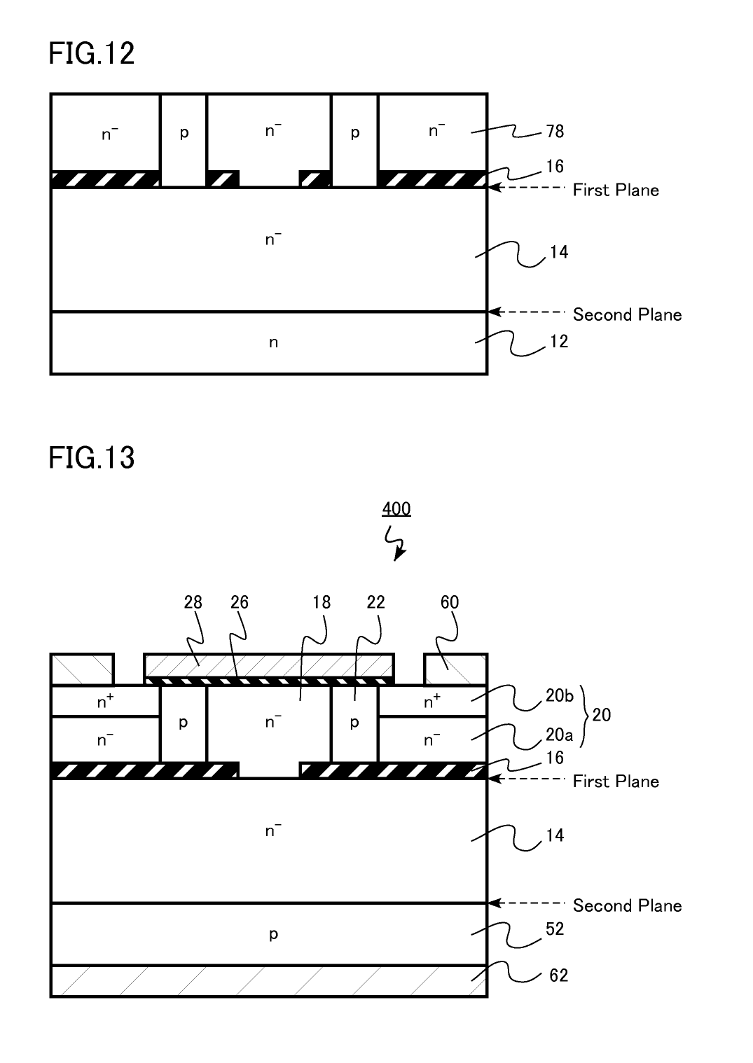

The p-type GaN layer 82 is then polished by CMP (Chemical Mechanical Polishing) (FIG. 12).

After that, the first GaN region 18, the second GaN region 20, the third GaN region 22, the gate insulating film 26, the gate electrode 28, the source electrode 30, and the drain electrode 32 are formed by the same manufacturing method as that of the first embodiment. By the above described manufacturing method, the MISFET 300 shown in FIG. 9 is formed.

According to this embodiment, the portions of the GaN layer 14 as the bottom portions of the trenches 80 can also serve as seed crystals when the p-type GaN layer 82 is formed. Accordingly, the p-type GaN layer 82 with higher quality can be readily manufactured.

### Third Embodiment

A semiconductor device of this embodiment is the same as the first embodiment, except that the n-type nitride semiconductor substrate is replaced with a p-type nitride semiconductor substrate. Therefore, explanation of the same aspects as those of the first embodiment will not be repeated.

FIG. 13 is a schematic cross-sectional view of the semiconductor device of this embodiment. The semiconductor device of this embodiment is an IGBT (Insulated Gate Bipolar Transistor).

This IGBT 400 includes a p-type GaN substrate (a nitride semiconductor substrate) 52, an n⁻-type GaN layer (a nitride semiconductor layer) 14, an insulating layer 16, an n⁻-type first GaN region (a first nitride semiconductor region) 18, an n-type second GaN region (a second nitride semiconductor region) 20, a p-type third GaN region (a third nitride semiconductor region) 22, a gate insulating film 26, a gate electrode 28, an emitter electrode (a first electrode) 60, and a collector electrode (a second electrode) 62.

The GaN substrate 52 functions as the drain region of the IGBT 400. The GaN substrate 52 contains Mg (magnesium) as the p-type impurity, for example.

The p-type impurity concentration in the GaN substrate 52 is not lower than 1×10¹⁸ cm⁻³ and not higher than 1×10²⁰ cm⁻³, for example. The thickness of the GaN substrate 52 is not smaller than 50 nm and not greater than 300 nm, for example.

The second GaN region 20 functions as the emitter region of the IGBT 400. The second GaN region 20 includes a low impurity concentration region 20a on the insulating layer 16, and a high impurity concentration region 20b on the low impurity concentration region 20a. The second GaN region 20 has a stack structure of the low impurity concentration region 20a and the high impurity concentration region 20b. The second GaN region 20 contains Si (silicon) as the n-type impurity, for example.

The emitter electrode 60 that is electrically connected to the second GaN region 20 is then formed. The emitter electrode 60 is formed on the high impurity concentration region 20b.

The emitter electrode 60 and the high impurity concentration region 20b preferably form ohmic contact therebetween. The emitter electrode 60 has a stack structure of Ti (titanium)/Al (aluminum)/Ti (titanium), for example.

The collector electrode 62 is formed on the opposite side of the p-type GaN substrate 52 from the GaN layer 14. The collector electrode 62 has a stack structure of Ni (nickel)/Ag (silver)/Ti (titanium), for example.

According to this embodiment, the IGBT 400 whose threshold value can be readily adjusted is realized.

Although the material of each nitride semiconductor is GaN in the above described embodiments, it is also possible to use another nitride semiconductor such as any other GaN-based semiconductor.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
an n-type nitride semiconductor layer;
an insulating layer selectively provided above the nitride semiconductor layer;
an n-type first nitride semiconductor region provided above the nitride semiconductor layer and the insulating layer;
an n-type second nitride semiconductor region provided above the insulating layer;
a p-type third nitride semiconductor region provided between the first nitride semiconductor region and the second nitride semiconductor region;
a gate insulating film provided above the third nitride semiconductor region;
a gate electrode provided above the gate insulating film;
a first electrode electrically connected to the second nitride semiconductor region; and
a second electrode provided at the opposite side of the nitride semiconductor layer from the insulating layer, the second electrode being electrically connected to the nitride semiconductor layer.

2. The device according to claim 1, wherein the third nitride semiconductor region is provided above the insulating layer.

3. The device according to claim 1, wherein a thickness of the first nitride semiconductor region is smaller than a thickness of the nitride semiconductor layer.

4. The device according to claim 1, wherein the third nitride semiconductor region is an epitaxially grown layer.

5. The device according to claim 1, wherein a p-type impurity concentration in the third nitride semiconductor region is not lower than 1×10¹⁷ cm⁻³ and not higher than 1×10¹⁹ cm⁻³.

6. The device according to claim 1, wherein the insulating layer is a silicon oxide film.

7. The device according to claim 1, wherein an n-type impurity concentration in the first nitride semiconductor region is higher than an n-type impurity concentration in the nitride semiconductor layer.

8. The device according to claim 1, wherein an n-type nitride semiconductor substrate having a higher n-type impurity concentration than an n-type impurity concentration in the nitride semiconductor layer is provided between the nitride semiconductor layer and the second electrode.

9. The device according to claim 1, wherein the third nitride semiconductor region is provided on the nitride semiconductor layer.

10. The device according to claim 1, wherein an n-type impurity concentration in the second nitride semiconductor region is higher than an n-type impurity concentration in the first nitride semiconductor region.
